(19) United States
(12) Patent Application Publication
(10) Pub. No.: US 2013/0330928 A1
(43) Pub. Date: Dec. 12, 2013

(54) FILM FORMING DEVICE, SUBSTRATE PROCESSING SYSTEM AND SEMICONDUCTOR DEVICE MANUFACTURING METHOD

(71) Applicants: Hiraku Ishikawa, Sendai (JP); Teruyuki Hayashi, Nirasaki (JP); Takaaki Matsuoka, Tokyo (JP); Yuji Ono, Oshu (JP)

(72) Inventors: Hiraku Ishikawa, Sendai (JP); Teruyuki Hayashi, Nirasaki (JP); Takaaki Matsuoka, Tokyo (JP); Yuji Ono, Oshu (JP)

(73) Assignee: TOKYO ELECTRON LIMITED, Tokyo (JP)

(21) Appl. No.: 13/978,438

(22) PCT Filed: Jan. 5, 2012
(86) PCT No.: PCT/JP2012/050079

§ 371 Date: Aug. 28, 2013

(30) Foreign Application Priority Data
Jan. 5, 2011 (JP) 2011-000438

(51) Int. Cl. H01L 21/67; H01L 21/308

(52) U.S. Cl. CPC H01L 21/67069; H01L 21/3081
USPC 438/694; 118/728; 118/729; 118/708

(57) ABSTRACT

A substrate processing system of forming a resist pattern having a molecular resist of a low molecular compound on a substrate includes a film forming device configured to form a resist film on the substrate; an exposure device configured to expose the formed resist film; and a developing device configured to develop the exposed resist film. The film forming device includes a processing chamber configured to accommodate therein the substrate; a holding table that is provided in the processing chamber and configured to hold the substrate thereon; a resist film deposition head configured to supply a vapor of the molecular resist to the substrate held on the holding table; and a depressurizing device configured to depressurize an inside of the processing chamber to a vacuum atmosphere.

### TECHNICAL FIELD

The present disclosure relates to a film forming device for forming a resist film having a molecular resist of a low molecular compound on a substrate, a substrate processing system, a substrate processing method, and a semiconductor device manufacturing method.

### BACKGROUND ART

By way of example, during a photolithography process in a manufacturing process of a semiconductor device, a resist coating process for forming a resist film by supplying a resist liquid onto a semiconductor wafer (hereinafter, referred to as “wafer”), an exposure process for exposing the resist film in a certain pattern, and a developing process for developing the exposed resist film are performed in sequence. Thus, a certain resist pattern is formed on the wafer.

When the resist pattern is formed as described above, in order to achieve further high integration of a semiconductor device, miniaturization of the resist pattern has been required in recent years. Therefore, a wavelength of a light used for the exposure process has been shortened. To be specific, conventionally, as an exposure light source, there has been used a light source that outputs, for example, a KrF laser (wavelength: 248 nm), an ArF laser (wavelength: 193 nm) or a F2 laser (wavelength: 157 nm). However, there has been developed a use of a light source that outputs, for example, an extreme ultra violet (EUV) ray having a shorter wavelength of about 13 nm to about 14 nm as compared with these lasers.

Meanwhile, conventionally, there has been used a high molecular compound as a molecular resist in a resist liquid in order to easily perform a resist coating process. Such a high molecular compound has a large molecular size and there is formed a strong entanglement of molecular chains, and, thus, it is difficult to resolve the high molecular compound into a fine pattern in the exposure process. As a result, particularly, line edge roughness (LER) or line width roughness (LWR) of a resist pattern is increased.

Accordingly, there has been suggested a molecular resist of a low molecular compound (hereinafter, referred to as “low molecular resist”), which is used in an exposure apparatus that outputs a light, such as a EUV ray, having a short wavelength (Patent Document 1).
Patent Document 1: Japanese Patent Laid-open Publication No. 2009-198605

### DISCLOSURE OF THE INVENTION

### Problems to be Solved by the Invention

In the above-described resist coating process, there has been typically used a so-called spin-coating method in which a resist liquid is coated on a wafer by supplying the resist liquid toward the center of the wafer being rotated through a nozzle and diffusing the resist liquid on the wafer by a centrifugal force.

However, if a resist liquid formed by dissolving a low molecular resist described in Patent Document 1 in a solvent is coated on a wafer by using such a spin-coating method, there is concern as follows.

That is, in the spin-coating method, it is difficult to uniformly diffuse the resist liquid on the wafer. In particular, if a thin resist film of the resist liquid is formed on the wafer, it is difficult to uniformly control a film thickness. Further, in the low molecular resist, there is formed a weak entanglement of the molecular chains. Therefore, if the low molecular resist is coated on the wafer, it is easy to be crystallized. As a result, LER or LWR of a resist pattern is increased. Even if the wafer is heat-processed after the resist liquid is supplied onto the wafer, the solvent of the resist liquid may remain on the wafer. In this case, in a subsequent exposure process, a vacuum level of a processing gas atmosphere is deteriorated due to the remaining solvent, and, thus, the exposure process cannot be performed appropriately.

In view of the foregoing, the present disclosure provides appropriately forming a resist film having a molecular resist of a low molecular compound on a substrate.

### Means for Solving the Problems

In accordance with an illustrative embodiment of the present disclosure, there is provided a film forming device of forming a resist film having a molecular resist of a low molecular compound on a substrate. The film forming device includes a processing chamber configured to accommodate therein the substrate; a holding table that is provided in the processing chamber and configured to hold the substrate thereon; a resist film deposition head configured to supply a vapor of the molecular resist to the substrate held on the holding table; and a depressurizing device configured to depressurize an inside of the processing chamber to a vacuum atmosphere. Further, the low molecular compound includes a compound having a low molecular weight of, for example, about 2000 or less.

In accordance with the illustrative embodiment of the present disclosure, the resist film can be formed by supplying a vapor of the molecular resist onto the substrate and depositing the molecular resist on the substrate under a vacuum atmosphere. In this case, by controlling a supply amount of the vapor of the molecular resist, a film thickness of the resist film on the substrate can be adjusted, so that the resist film has a uniform film thickness in an entire surface of the substrate. Further, since the vapor is supplied onto the substrate under a vacuum atmosphere, the molecular resist is supplied in an amorphous phase. Therefore, even if the molecular resist is a low molecular compound, the molecular resist is difficult to be crystallized. Accordingly, even if the resist film on the substrate is patterned, it is possible to reduce LER or LWR of the resist pattern. Furthermore, since the vapor supplied onto the substrate does not contain a solvent for dissolving the molecular resist, the solvent does not remain on the substrate unlike the conventional cases. Therefore, in a subsequent exposure process, it is possible to prevent a vacuum level of a processing gas atmosphere from being deteriorated due to the remaining solvent, so that the exposure process can be performed appropriately. As described above, in accordance with the present disclosure, it is possible to appropriately form a resist film having the molecular resist of the low molecular compound on the substrate.

In accordance with another illustrative embodiment of the present disclosure, there is provided a substrate processing system of forming a resist pattern having a molecular resist of a low molecular compound on a substrate. The substrate processing system includes a film forming device configured to form a resist film on the substrate; an exposure device configured to expose the formed resist film; and a developing device configured to develop the exposed resist film. Further, the film forming device includes a processing chamber configured to accommodate therein the substrate; a holding table that is provided in the processing chamber and configured to hold the substrate thereon; a resist film deposition head configured to supply a vapor of the molecular resist to the substrate held on the holding table; and a depressurizing device configured to depressurize an inside of the processing chamber to a vacuum atmosphere.

Further, in accordance with still another illustrative embodiment of the present disclosure, there is provided a substrate processing method of forming a resist pattern having a molecular resist of a low molecular compound on a substrate. The substrate processing method includes forming a resist film by supplying a vapor of the molecular resist onto the substrate and depositing the molecular resist on the substrate under a vacuum atmosphere; performing a first heat treatment on the resist film after forming the resist film; exposing the resist film after performing the first heat treatment; performing a second heat treatment on the resist film after exposing the resist film; developing the resist film after performing the second heat treatment; and performing a third heat treatment on the resist film after developing the resist film.

Furthermore, in accordance with still another illustrative embodiment of the present disclosure, there is provided a semiconductor device manufacturing method includes forming a resist pattern having a molecular resist of a low molecular compound on a substrate by performing a substrate processing method; and etching a target film on the substrate is performed by using the resist pattern as a mask after forming the resist pattern. The substrate processing method includes forming a resist film by supplying a vapor of the molecular resist onto the substrate and depositing the molecular resist on the substrate under a vacuum atmosphere; performing a first heat treatment on the resist film after forming the resist film; exposing the resist film after performing the first heat treatment; performing a second heat treatment on the resist film after exposing the resist film; developing the resist film after performing the second heat treatment; and performing a third heat treatment on the resist film after developing the resist film.

### Effect of the Invention

In accordance with the present disclosure, it is possible to appropriately form a resist film having a molecular resist of a low molecular compound on a substrate.

### BRIEF DESCRIPTION OF THE DRAWINGS

FIG. 1 is a plane view illustrating a schematic configuration of a wafer processing system in accordance with a present illustrative embodiment.

FIG. 2 is a longitudinal cross-sectional view illustrating a schematic configuration of a film forming device in accordance with the illustrative embodiment.

FIG. 3 is a perspective view of a sacrificial film deposition head.

FIGS. 4A to 4E provide explanatory diagrams illustrating a wafer status in a wafer process, and specifically, FIG. 4A illustrates a status where a target film is previously formed on a wafer; FIG. 4B illustrates a status where a sacrificial film is formed on the target film; FIG. 4C illustrates a status where an anti-reflection film is formed on the sacrificial film; FIG. 4D illustrates a status where a resist film is formed on the anti-reflection film; and FIG. 4E illustrates a status where a resist pattern is formed in the resist film.

FIG. 5 is a plane view illustrating a schematic configuration of a wafer processing system in accordance with another illustrative embodiment.

FIG. 6 is a plane view illustrating a schematic configuration of a wafer processing system in accordance with still another illustrative embodiment.

FIG. 7 is a longitudinal cross-sectional view illustrating a schematic configuration of a film forming device in accordance with still another illustrative embodiment.

### BEST MODE FOR CARRYING OUT THE INVENTION

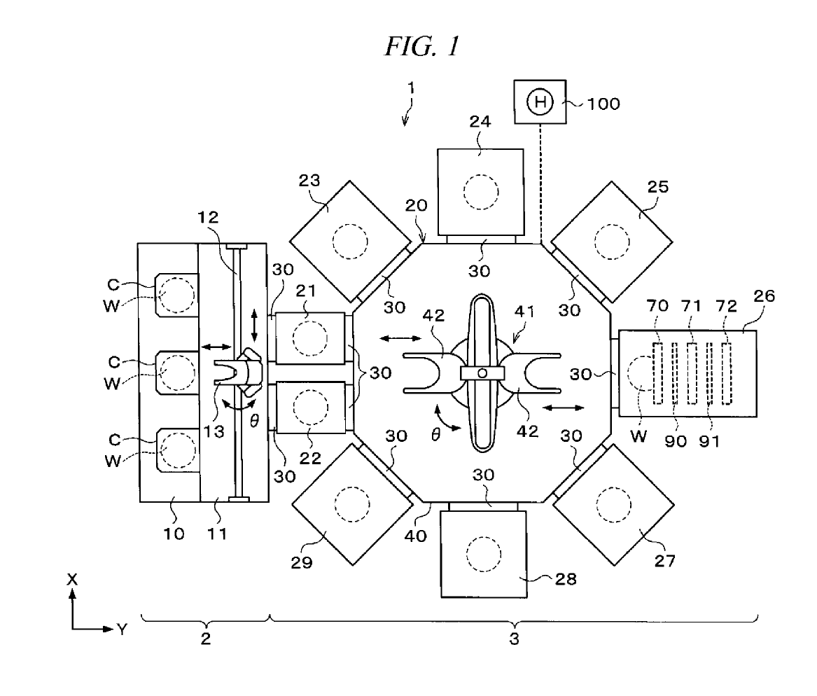

Hereinafter, illustrative embodiments will be described. FIG. 1 is a plane view illustrating a schematic configuration of a wafer processing system 1 as a substrate processing system in accordance with the present illustrative embodiment. The wafer processing system 1 in accordance with the illustrative embodiment performs a photolithography process on a wafer W as a substrate and forms a resist pattern on the wafer W. Further, on the wafer W processed in the wafer processing system 1, as described below, a target film, for example, a silicon nitride film (SiN) and a silicon oxide film (SiO₂), is previously formed.

Further, a resist used in the present illustrative embodiment is a so-called chemically amplified resist, and has photosensitivity. Further, the resist used in the present illustrative embodiment is a molecular resist of a low molecular compound (hereinafter, referred to as “low molecular resist”) having a molecular weight of, for example, about 2000 or less, and more desirably, about 1000 or less as described below.

As depicted in FIG. 1, the wafer processing system 1 includes a loading/unloading station 2 as a substrate loading/unloading unit and a processing station 3, which are connected with each other in one single body. The loading/unloading station 2 is configured to load and unload, for example, multiple wafers W in a cassette unit between the wafer processing system 1 and an outside, or is configured to loads and unloads the wafer W with respect to a cassette C or a main transfer chamber 20 to be described later. Further, the processing station 3 includes multiple processing devices configured to perform respective processes in the single wafer process.

The loading/unloading station 2 includes a cassette mounting table 10. The cassette mounting table 10 is configured to mount multiple cassettes C thereon in a single row in an X-direction (in a vertical direction of FIG. 1). That is, the loading/unloading station 2 is configured to accommodate multiple wafers W.

In the loading/unloading station 2, the cassette mounting table 10 is adjacent to a transfer chamber 11 at a positive Y-direction side (at a right direction side of FIG. 1). The transfer chamber 11 includes a wafer transfer body 13 that is movable along a transfer path 12 extended in the X-direction. The wafer transfer body 13 is extensible and contractible in a horizontal direction and movable in the vertical direction and rotatable about a vertical center (in a θ-direction). The wafer transfer body 13 is configured to transfer the wafer W between the cassette C and load-lock chambers 21 and 22, which will be descried later, of the processing station 3.

At a central portion of the processing station 3, there is provided the main transfer chamber 20 as a substrate transfer unit capable of depressurizing an inside thereof. The main transfer chamber 20 has, for example, a substantially polygonal shape (an octagonal shape in the drawing) when viewed from the top. Further, the main transfer chamber 20 is surrounded by and connected to the load-lock chambers 21 and 22 and, for example, seven (7) processing devices 23, 24, 25, 26, 27, 28, and 29. The load-lock chambers 21 and 22, and the processing devices 23, 24, 25, 26, 27, 28, and 29 are arranged in this sequence in a clockwise direction around the main transfer chamber 20 when viewed from the top.

Between the transfer chamber 11 and the respective load-lock chambers 21 and 22, between the main transfer chamber 20 and the respective load-lock chambers 21 and 22, and between the main transfer chamber 20 and the respective processing devices 23 to 29, there are provided gate valves 30 each configured to airtightly seal a space therebetween and also configured to be opened and closed.

The main transfer chamber 20 includes a transfer chamber 40 configured to seal an inside thereof. Within the transfer chamber 40, there is provided a wafer transfer device 41 configured to transfer the wafer W. The wafer transfer device 41 includes two transfer arms 42 and 42 that hold the wafer W in a substantially horizontal manner. Each of the transfer arms 42 is configured to be extensible and contractible in the horizontal direction and movable in the vertical direction, and rotatable about the vertical center (in the θ-direction). Further, the wafer transfer device 41 can transfer the wafer W with respect to the load-lock chambers 21 and 22 and with respect to the processing devices 23 to 29 around the main transfer chamber 20.

The load-lock chambers 21 and 22 are provided between the main transfer chamber 20 and the transfer chamber 11 of the loading/unloading station 2, and connect the main transfer chamber 20 with the transfer chamber 11. Each of the load-lock chambers 21 and 22 includes a mounting unit (not illustrated) that mounts thereon the wafer W and maintains the inside under a depressurized atmosphere. Hereinafter, the load-lock chamber 21 may be referred to as “first load-lock chamber 21” and the load-lock chamber 22 may be referred to as “second load-lock chamber 22”.

The processing device 23 is a pre-processing device configured to clean a surface (a surface on which a target film is formed) of the wafer W. By way of example, the pre-processing device 23 irradiates ultraviolet rays to the surface of the wafer W. As a result, organic materials or the like are removed from the surface of the wafer W by irradiating the ultraviolet rays, and the surface of the wafer W is cleaned. The surface of the wafer W may be cleaned by converting a processing gas such as an argon gas into plasma and supplying the plasma to the surface of the wafer W.

The processing devices 24 and 25 are heat treatment devices 24 and 25 configured to perform a heat treatment on the wafer W. Each of the heat treatment devices 24 and 25 includes, for example, a heating plate (not illustrated) configured to mount and heat the wafer W thereon; and a cooling plate (not illustrated) configured to mount and cool the wafer W thereon. The heat treatment devices 24 and 25 can perform both a heating process and a cooling process. Further, a heat treatment temperature in the heat treatment devices 24 and 25 is controlled by, for example, a control device 100 to be described later.

The processing device 26 is a film forming device 26 configured to form a resist film on the wafer W. A configuration of the film forming device 26 will be described later.

The processing device 27 is an exposure device 27 configured to perform an exposure process of the resist film on the wafer W. The exposure device 27 includes a light source (not illustrated) that outputs a EUV ray (wavelength: from about 13 nm to about 14 nm). Further, in the exposure device 27, EUV rays are irradiated to the resist film on the wafer W, and a certain pattern of the resist film is selectively exposed.

The processing device 28 is a developing device 28 configured to perform a developing process of the resist film on the wafer W. In the developing device 28, for example, a developing liquid is supplied to the resist film on the wafer W exposed in the exposure device 27. Further, the resist film is developed by the developing liquid, so that a resist pattern is formed on the wafer W. Furthermore, in the developing device 28, a dry development using, for example, a developing liquid in the form of plasma may be performed instead of a wet development using the above-described developing liquid. That is, a developing process within the developing device 28 may be performed under an atmospheric atmosphere or under a vacuum atmosphere. Therefore, if the developing process is performed under the atmospheric atmosphere, the wafer W is not necessarily transferred under a vacuum atmosphere and the developing process may be performed outside the wafer processing system 1.

The processing device 29 is a dimension measuring device 29 configured to measure a dimension of the resist pattern on the wafer W. In the dimension measuring device 29, a dimension of the resist pattern is measured by using, for example, a scatterometry method. The scatterometry method includes matching a light intensity distribution in the entire surface of the wafer detected by irradiating a light to the resist pattern on the target wafer W with a previously stored virtual light intensity distribution; and estimating an actual dimension of the resist pattern from a dimension of a virtual resist pattern corresponding to the light intensity distribution. In the present illustrative embodiment, as a dimension of the resist pattern, for example, a height of the resist pattern is measured.

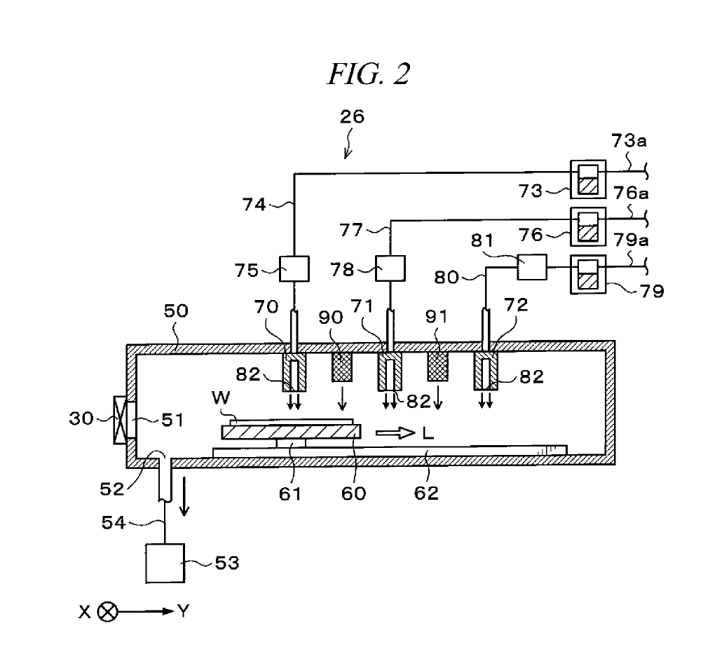

Hereinafter, a configuration of the above-described film forming device 26 will be explained. The film forming device 26, as depicted in FIG. 2, includes a processing chamber 50 configured to accommodate the wafer W and seal an inside thereof. At a side of the main transfer chamber 20 of the processing chamber 50, there is formed a loading/unloading port 51 through which the wafer W is loaded and unloaded. The above-described gate valve 30 is provided at the loading/unloading port 51.

At a bottom surface of the processing chamber 50, there is formed an air intake opening 52 through which an atmosphere within the processing chamber 50 is depressurized to a certain vacuum atmosphere. By way of example, the air intake opening 52 is connected to an air intake line 54 configured to communicate with a vacuum pump 53. Further, in the present illustrative embodiment, the air intake opening 52, the vacuum pump 53, and the air intake line 54 form a depressurizing unit of the present disclosure.

Within the processing chamber 50, there is provided a holding table 60 configured to horizontally hold the wafer W. The holding table 60 holds the wafer W by means of, for example, electrostatic attraction. Further, the wafer W is held on the holding table 60 in a face-up state where a surface on which a target film is formed faces upwards. Under the holding table 60, there is provided a driving unit 61 including, for example, a motor or the like. The driving unit 61 is provided at the bottom surface of the processing chamber 50 and installed on a rail 62 extended in the Y-direction. The holding table 60 can be moved along the rail by the driving unit 61 to transfer the wafer W. Furthermore, in the present illustrative embodiment, the Y-direction in which the rail 62 is extended is a transfer direction L of the wafer W. Moreover, in the present illustrative embodiment, the driving unit 61 and the rail 62 form a transfer unit of the present disclosure.

At a ceiling surface of the processing chamber 50, three (3) deposition heads 70, 71, and 72 are arranged in this sequence along the transfer direction L of the wafer W.

The deposition head 70 is a sacrificial film deposition head 70 configured to supply a vapor of a film forming material (hereinafter, referred to as “sacrificial film material”) for forming a sacrificial film, which serves as a mask when the target film on the wafer W is etched, onto the target film by using a carrier gas. As the sacrificial film material, there is used a material that is a low molecular compound sufficient to be supplied onto the wafer W from the sacrificial film deposition head 70 and has a high etching selectivity with respect to the target film. By way of example, a molecular compound having a benzene ring may be used. Further, in the preset illustrative embodiment, a resist film formed by the film forming device has a small film thickness, and, thus, if a resist pattern formed on the resist film is used as a mask, the target film may not be etched appropriately. For this reason, a sacrificial film serving as the mask of the target film is formed additionally in order to make up for the resist pattern in the present illustrative embodiment.

The sacrificial film deposition head 70 is connected to a vapor supply source 73 configured to supply a vapor of a sacrificial film material to the sacrificial film deposition head 70 via a vapor supply line 74. The vapor supply line 74 includes a supply unit group 75 having a valve and a supply amount control unit that control a flow of the vapor of the sacrificial film material. Further, the vapor supply source 73 is connected to a carrier gas supply line 73a through which a carrier gas is supplied into the vapor supply source 73. As the carrier gas, for example, an inert gas may be used. Furthermore, the carrier gas supplied into the vapor supply source 73 through the carrier gas supply line 73a is uniformly mixed in a certain concentration with the vapor of the sacrificial film material. The vapor of the sacrificial film material is supplied to the sacrificial film deposition head 70, and then, supplied from the sacrificial film deposition head 70 onto the target film by the carrier gas.

The deposition head 71 is an anti-reflection film deposition head 71 configured to supply a vapor of a film forming material (hereinafter, referred to as “anti-reflection film material”) for forming an anti-reflection film, which prevents light from being reflected during the exposure process, onto the sacrificial film by using a carrier gas. The anti-reflection film deposition head 71 is connected to a vapor supply source 76 configured to supply a vapor of an anti-reflection film material to the anti-reflection film deposition head 71 via a vapor supply line 77. The vapor supply line 77 includes a supply unit group having a valve and a supply amount control unit that control a flow of the vapor of the anti-reflection film material. Further, the vapor supply source 76 is connected to a carrier gas supply line 76a through which a carrier gas is supplied into the vapor supply source 76. As the carrier gas, for example, an inert gas may be used. Furthermore, the carrier gas supplied into the vapor supply source 76 through the carrier gas supply line 76a is uniformly mixed in a certain concentration with the vapor of the anti-reflection film material. The vapor of the anti-reflection film material is supplied to the anti-reflection film deposition head 71, and then, supplied from the anti-reflection film deposition head 71 onto the sacrificial film by the carrier gas.

The deposition head 72 is a resist film deposition head 72 configured to supply a vapor of a low molecular resist onto the anti-reflection film by using a carrier gas. As described above, the low molecular resist is a low molecular compound having a molecular weight of, for example, about 2000 or less, and more desirably, about 1000 or less. The resist film deposition head 72 is connected to a vapor supply source 79 configured to supply a vapor of a low molecular resist to the resist film deposition head 72 via a vapor supply line 80. The vapor supply line 80 includes a supply unit group 81 having a valve and a supply amount control unit that control a flow of the vapor of the low molecular resist. Further, the vapor supply source 79 is connected to a carrier gas supply line 79a through which a carrier gas is supplied into the vapor supply source 79. As the carrier gas, for example, an inert gas may be used. Furthermore, the carrier gas supplied into the vapor supply source 79 through the carrier gas supply line 79a is uniformly mixed in a certain concentration with the vapor of the low molecular resist material. The vapor of the low molecular resist material is supplied to the resist film deposition head 72, and then, supplied from the resist film deposition head 72 onto the anti-reflection film by the carrier gas.

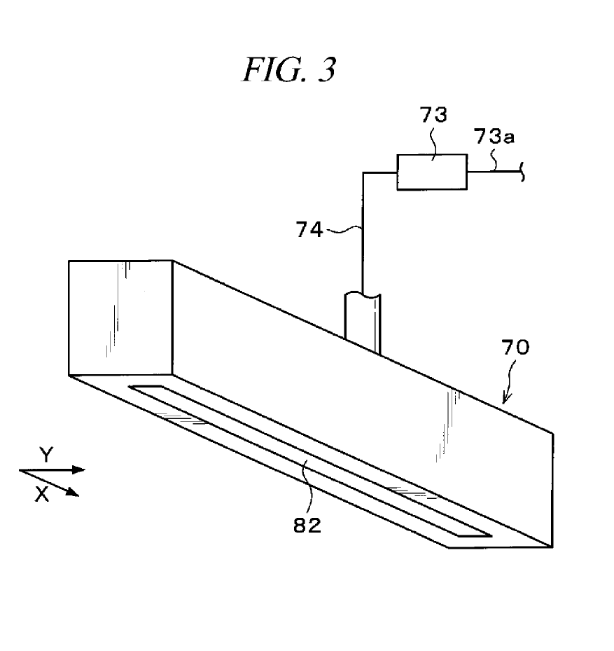

As depicted in FIGS. 2 and 3, each of the deposition heads 70, 71, and 72 has a substantially rectangular parallelepiped shape extended in a direction (in the X-direction in the drawings) perpendicular to the transfer direction L of the wafer W. Further, on a lower surface of each of the deposition heads 70, 71, and 72, there is formed a supply opening 82 configured to supply a vapor of a film forming material (a sacrificial film material, an anti-reflection film material, and a low-molecular material) onto the wafer W, respectively. Each supply opening 82 is extended in the direction (in the X-direction in the drawings) perpendicular to the transfer direction L of the wafer W and has a length greater than an X-directional length of the wafer W. With this configuration, the vapors of the film forming materials are uniformly supplied in the lengthwise direction of the wafer W from each of the deposition heads 70, 71, and 72. Furthermore, although FIG. 3 illustrates the sacrificial film deposition head 70, the anti-reflection film deposition head 71 and the resist film deposition head 72 have the same configuration.

While the wafer W held on the holding table 60 is transferred along the transfer direction L, the vapor of the sacrificial film material, the vapor of the anti-reflection film material, and the vapor of the low molecular resist film material are supplied in this sequence onto the wafer W from the deposition heads 70, 71, and 72, respectively. Thus, the sacrificial film, the anti-reflection film, and the resist film are formed in this sequence on the target film on the wafer W. In this case, since the deposition heads 70, 71, and 72 supply the vapors of the film forming materials by using the carrier gases, the vapor of the film forming materials can be uniformly supplied onto the wafer W. Therefore, each of the sacrificial film, the anti-reflection film, and the resist film can also be uniformly formed on the target film on the wafer W. Further, by setting a distance between the deposition heads 70, 71, and 72 and the wafer W to be short, the vapors of the film forming materials can be efficiently used.

At a ceiling surface of the processing chamber 50, as depicted in FIG. 2, between the sacrificial film deposition head 70 and the anti-reflection film deposition head 71, there is provided a first electron beam irradiating unit 90 as a first cross-linking unit configured to irradiate electron beams to the sacrificial film on the wafer W in order to cross-link the sacrificial film. Further, between the anti-reflection film deposition head 71 and the resist film deposition head 72, there is provided a second electron beam irradiating unit 91 as a second cross-linking unit configured to irradiate electron beams to an anti-reflection film on the wafer W in order to cross-link the anti-reflection film. Each of the first electron beam irradiating unit 90 and the second electron beam irradiating unit 91 is extended in the direction (in the X-direction in the drawings) perpendicular to the transfer direction L of the wafer W and has a length greater than the X-directional length of the wafer W. With this configuration, electron beams are uniformly irradiated from the first electron beam irradiating unit 90 and the second electron beam irradiating unit 91 in the lengthwise direction of the wafer W. Although the first electron beam irradiating unit 90 and the second electron beam irradiating unit 91 irradiate electron beams to the sacrificial film and the anti-reflection film, respectively, in the present illustrative embodiment, instead of the electron beams, any other member may be used if it is capable of cross-linking the sacrificial film and the anti-reflection film. By way of example, ultraviolet rays or charged particle beams such as other electron beams may be irradiated to the sacrificial film and the anti-reflection film.

In the above-described wafer processing system 1, as depicted in FIG. 1, the control device 100 is provided. The control device 100 is, for example, a computer and includes a program storage unit (not illustrated). The program storage unit stores a program for performing wafer processes within the wafer processing system 1. Further, this program is stored in computer-readable storage medium H such as computer-readable hard disk (HD), a flexible disk (FD), a compact disk (CD), a magnet-optical desk (MO), a memory card, and the like and may be installed from the storage medium H to the control device 100.

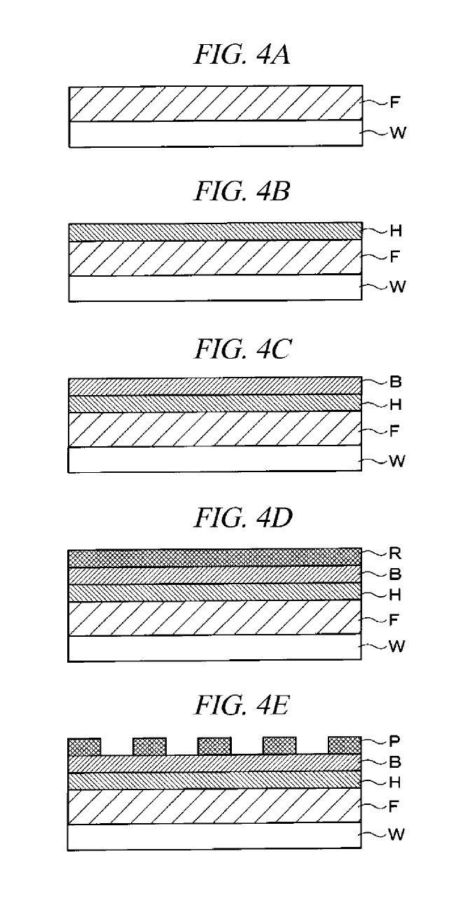

Hereinafter, a wafer process performed in the wafer processing system 1 configured as described above will be explained. FIGS. 4A to 4E illustrate a wafer status in main processes of wafer processes. Further, as depicted in FIG. 4A, a target film F is previously formed on a wafer W to be processed in the wafer processing system 1. As describe above, the target film F is, for example, a silicon nitride film (SiN) and a silicon oxide film (SiO₂).

The wafer W is taken out of the cassette C on the cassette mounting table 10 in the loading/unloading station 2 by the wafer transfer body 13 and transferred to the first load-lock chamber 21. Then, the gate valve 30 at a side of loading/unloading station 2 of the first load-lock chamber 21 is closed. Thereafter, an inside of the first load-lock chamber 21 is exhausted to be depressurized to a certain vacuum atmosphere.

Then, the gate valve 30 between the main transfer chamber 20 and the first load-lock chamber 21 is opened and the wafer W within the first load-lock chamber 21 is transferred to the main transfer chamber 20 by the wafer transfer device 41. In this case, the inside of the main transfer chamber 20 is maintained under the certain vacuum atmosphere.

When the wafer W is transferred into the main transfer chamber 20, the gate valve 30 between the main transfer chamber 20 and the first load-lock chamber 21 is closed. Then, the respective processing devices 23 to 29 perform preset processes on the wafer W. The wafer W is transferred to the respective processing devices 23 to 29 by the wafer transfer device 41. When the wafer transfer device 41 loads and unloads the wafer W with respect to the respective processing devices 23 to 29, the corresponding gate valves 30 are opened and closed. Hereinafter, an explanation of opening and closing of the gate valves 30 between the main transfer chamber 20 and the respective processing devices 23 to 29 will be omitted.

Then, the wafer W within the main transfer chamber 20 is transferred to the pre-processing device 23 by the wafer transfer device 41. In the pre-processing device 23, ultraviolet rays are irradiated to a surface of the wafer W. Thus, organic materials or the like on the wafer W, i.e., on the target film F on the wafer W, are removed, so that the surface of the wafer W is cleaned.

Thereafter, the wafer W within the pre-processing device 23 is transferred to the film forming device 26 via the main transfer chamber 20 by the wafer transfer device 41. The wafer W transferred into the film forming device 26 is held on the holding table 60 in a state where a surface on which the target film F is formed faces upwards. The wafer W held on the holding table 60 is transferred along the transfer direction L. Further, while the wafer W is processed in the film forming device 26, the inside of the processing chamber 50 of the film forming device 26 is maintained under a certain vacuum atmosphere by the vacuum pump 53.

In the film forming device 26, vapor of a sacrificial film material is supplied from the sacrificial film deposition head 70 onto the target film F on the wafer W being transferred. Further, as depicted in FIG. 4B, the sacrificial film material is deposited on the target film F, so that a sacrificial film H is formed. Then, electron beams are irradiated from the first electron beam irradiating unit 90 to the sacrificial film H, and the sacrificial film material in the sacrificial film H is cross-linked. Thus, the sacrificial film H is appropriately formed on the target film F.

Thereafter, vapor of an anti-reflection film material is supplied from the anti-reflection film deposition head 71 onto the sacrificial film H on the wafer W. Further, as depicted in FIG. 4C, the anti-reflection film material is deposited on the sacrificial film H, so that an anti-reflection film B is formed. Then, electron beams are irradiated from the second electron beam irradiating unit 91 to the anti-reflection film B, and the anti-reflection film material in the anti-reflection film B is cross-linked. Thus, the anti-reflection film B is appropriately formed on the sacrificial film H.

Subsequently, vapor of a low molecular resist is supplied from the resist film deposition head 72 onto the anti-reflection film B on the wafer W. Further, as depicted in FIG. 4D, the low molecular resist is deposited on the anti-reflection film B, so that a resist film R is formed on the anti-reflection film B.

Further, in the film forming device 26, supply amounts of the vapor supplied from the respective deposition heads 70, 71, and 72 are controlled such that a film thickness of the sacrificial film H, a film thickness of the anti-reflection film B, and a film thickness of the resist film R have certain film thicknesses, respectively.

When the resist film R is formed on the wafer W, the wafer W within the film forming device 26 is transferred to the heat treatment device 24 via the main transfer chamber 20 by the wafer transfer device 41. In the heat treatment device 24, the wafer W is heated, and a so-called pre-baking process (PAB process) is performed thereon.

Then, the wafer W within the heat treatment device 24 is transferred to the exposure device 27 via the main transfer chamber 20 by the wafer transfer device 41. In the exposure device 27, EUV rays are irradiated to the resist film R on the wafer W, and a certain pattern of the resist film R is selectively exposed.

Thereafter, the wafer W within the exposure device 27 is transferred to the heat treatment device 25 via the main transfer chamber 20 by the wafer transfer device 41. In the heat treatment device 25, the wafer W is heated, and a so-called post exposure backing process (PEB process) is performed thereon.

Subsequently, the wafer W within the heat treatment device 25 is transferred to the developing device 28 via the main transfer chamber 20 by the wafer transfer device 41. In the developing device 28, a developing liquid is supplied to the exposed resist film R and the resist film R is developed. Thus, as depicted in FIG. 4E, a resist pattern P is formed on the anti-reflection film B on the wafer W.

Then, the wafer W within the developing device 28 is transferred to the heat treatment device 25 via the main transfer chamber 20 by the wafer transfer device 41. In the heat treatment device 25, the wafer W is heated, and a so-called post backing process (POST process), is performed thereon.

Thereafter, the wafer W within the heat treatment device 25 is transferred to the dimension measuring device 29 via the main transfer chamber 20 by the wafer transfer device 41. In the dimension measuring device 29, a height of the resist pattern P is measured by the scatterometry method.

A measurement result of the dimension measuring device 29 is outputted to the control device 100. In the control device 100, if the measured height of the resist pattern P is not a required height, a processing condition of the film forming device 26 is changed based on the measurement result. To be specific, a temperature and a supply amount of the vapor of the low molecular resist supplied from the resist film deposition head 72 is changed. Further, any one of the temperature and the supply amount of the vapor of the low molecular resist may be changed. In this way, the processing condition of the film forming device 26 is feedback controlled. Further, a next wafer W is processed under the changed processing condition and a resist film R having a required film thickness is formed on the wafer W.

Then, the wafer W within the dimension measuring device 29 is transferred to the second load-lock chamber 22 via the main transfer chamber 20 by the wafer transfer device 41. In this case, an inside of the second load-lock chamber 22 is depressurized to a certain vacuum atmosphere. Thereafter, the wafer W is transferred to the cassette C on the cassette mounting table 10 in the loading/unloading station 2 by the wafer transfer body 13. Thus, a series of wafer processes in the wafer processing system 1 is ended.

In accordance with the above-described illustrative embodiment, in the film forming device 26, the vapor of the low molecular resist is supplied onto the wafer W from the resist film deposition head 72 and the low molecular resist is deposited on the wafer W under a vacuum atmosphere, so that the resist film R is formed. In this case, by adjusting a supply amount of the vapor of the low molecular resist, a film thickness of the resist film R on the wafer W can be adjusted and a film thickness of the resist film R can be uniform in the entire surface of the wafer W. Further, since the supply opening 82 of the resist film deposition head 72 is extended to have the length greater than the length of the wafer W, the vapor of the low molecular resist is uniformly supplied in the lengthwise direction of the wafer W. Therefore, a film thickness of the resist film R can be further uniform in the entire surface of the wafer W.

In the film forming device 26, since the vapor of the low molecular resist is supplied onto the wafer W under a vacuum atmosphere, the low molecular resist is supplied in an amorphous phase. Therefore, even if the molecular resist is a low molecular compound, the low molecular resist is difficult to be crystallized. Accordingly, it is possible to reduce LER or LWR of the resist pattern P formed on the wafer W.

Furthermore, in the film forming device 26, since the vapor of the low molecular resist supplied onto the wafer W does not contain a solvent for dissolving the molecular resist, the solvent does not remain on the wafer W unlike the conventional cases. Therefore, in a subsequent exposure process in the exposure device 27, it is possible to prevent a vacuum level of a processing gas atmosphere from being deteriorated due to the remaining solvent, so that the exposure process can be performed appropriately.

Moreover, in the film forming device 26, the sacrificial film H, the anti-reflection film B, and the resist film R are formed in this sequence on the target film F on the wafer W. Since different kinds of films can be formed in a single device, it is possible to increase a throughput of the wafer processes. The sacrificial film H, the anti-reflection film B, and the resist film R are formed by using the vapor of the sacrificial film material, the vapor of the anti-reflection film material, and the vapor of the low molecular resist, respectively. That is, in order to form these films, solvents of the film forming materials are not used. Therefore, a solvent of a film forming material does not damage another film, and the sacrificial film H, the anti-reflection film B, and the resist film R can be formed appropriately. Further, interfaces between the sacrificial film H, the anti-reflection film B, and the resist film R can be clearly defined.

In the film forming device 26, since electron beams are irradiated to the sacrificial film H and the anti-reflection film B on the wafer W, the sacrificial film H and the anti-reflection film B can be cross-linked. Therefore, the sacrificial film H and the anti-reflection film B can be formed appropriately.

Since the wafer processing system 1 includes the above-described film forming device 26, the wafer processing system 1 can form the resist pattern P appropriately on the wafer W. Further, since the wafer processing system 1 includes the configuration in which the respective processing devices 23 to 29 for performing wafer processes are connected to the main transfer chamber 20, the wafer processing system 1 can efficiently perform the wafer processes.

Further, in the wafer processing system 1, since a processing condition of the film forming device 26 is feedback controlled based on the height of the resist pattern P formed on the wafer W by the wafer processing system 1, a next wafer W can be processed appropriately. Thus, it is possible to increase a yield of semiconductor devices as products.

In the above-described illustrative embodiment, a height of the resist pattern P on the wafer W is measured by the dimension measuring device 29, but other dimensions of the resist pattern P may be measured. By way of example, a line width of the resist pattern P, a sidewall angle of the resist pattern P, a diameter of a contact hole, and the like may be measured. Even if any one of dimensions of the resist pattern is measured, the processing condition of the film forming device 26 can be feedback controlled based on the measurement result.

Further, in the above-described illustrative embodiment, the processing condition of the film forming device 26 is changed based on a measurement result of the dimension of the resist pattern P measured by the dimension measuring device 29. However, for example, processing conditions of the heat treatment devices 24 and 25 or a processing condition of the exposure device 29 may be changed. The processing conditions of the heat treatment conditions 24 and 25 may include, for example, a heat treatment temperature, a heat treatment time of the wafer W or the like. Further, the processing condition of the exposure device 29 may include, for example, an exposure amount (a dose amount of light from an exposure light source), a focus value in the exposure process or the like. Any one or a multiple number of the processing condition of the film forming device 26, the processing conditions of the heat treatment devices 24 and 25, and the processing condition of the exposure device 29 may be changed.

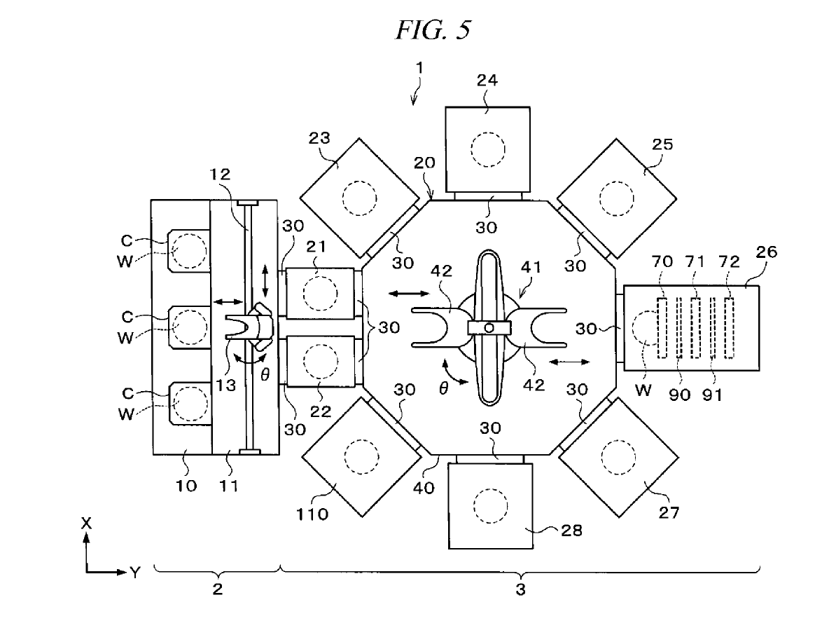

In the above-described illustrative embodiment, the wafer processing system 1 includes the dimension measuring device 29 configured to measure a dimension of the resist pattern P on the wafer W. However, as depicted in FIG. 5, the wafer processing system 1 may include a film thickness measuring device 110 configured to measure a film thickness of the resist film R on the wafer W. Further, in the drawing, the film thickness measuring device 110 is provided instead of the dimension measuring device 29. However, both the dimension measuring device 29 and the film thickness measuring device 110 may be provided within the wafer processing system 1.

The film thickness measuring device 110 is configured to measure a dimension of the resist film R by using an ellipsometry method. The ellipsometry method includes irradiating a light to the target resist film R on the wafer W; measuring a polarization state change between an incident light and a reflected light when the light is reflected; and calculating a film thickness of the resist film R based on the measurement result.

If the resist film R is formed on the wafer W by the film forming device 26, the film thickness measuring device 110 measures a film thickness of the resist film R. The measurement result of the film thickness measuring device 110 is outputted to the control device 100. In the control device 100, if the measured film thickness of the resist film R is not a required film thickness, a processing condition of the film forming device 26 is changed based on the measurement result. To be specific, at least one of a temperature and a supply amount of the vapor of the low molecular resist supplied from the resist film deposition head 72 is changed. Further, as a processing condition of the film forming device 26, a supply flow rate configured to transfer the vapor of the low molecular resist may be changed. In this way, the processing condition of the film forming device 26 can be feedback controlled. Further, a next wafer W is processed under the changed processing condition and a resist film R having a required film thickness is formed on the wafer W.

In the above-described illustrative embodiment, the loading/unloading station 2 of the wafer processing system 1 loads and unloads the wafer W with respect to the processing station 3. However, a loading unit and an unloading unit of the wafer W with respect to the processing station may be separately provided, and the wafer W may be processed while being transferred in a single direction.

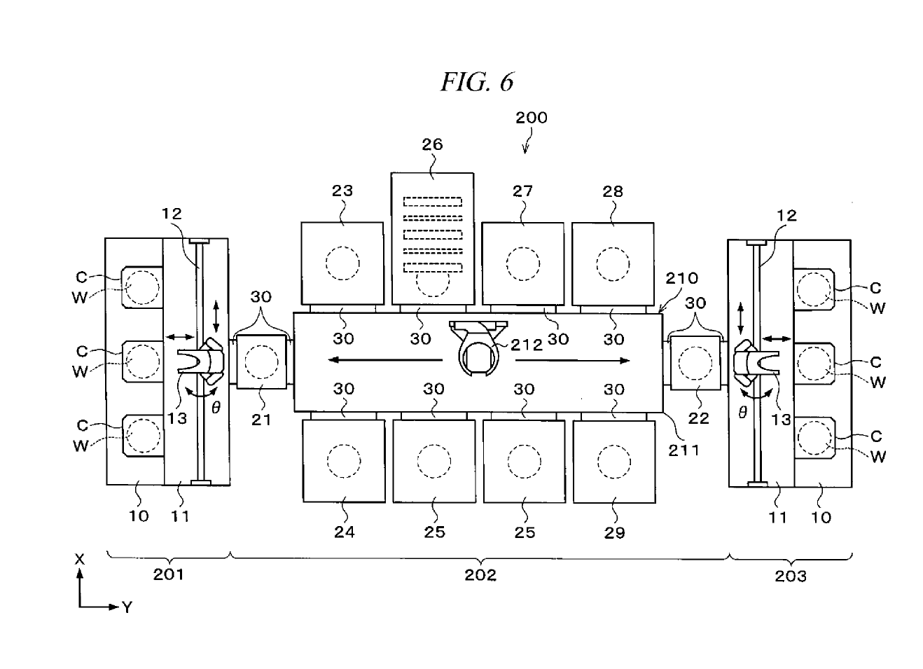

In this case, as depicted in FIG. 6, a wafer processing system 200 includes a configuration in which a loading station 201; a processing station 202; and an unloading station 203, which are provided as one single body in a Y-direction. The loading station 201 serving as a substrate loading unit is configured to load multiple wafers W into the wafer processing system 200 from the outside or load the wafers W into a main transfer chamber 210 to be described later. The processing station 202 includes multiple processing devices for performing respective preset processes on the wafer W. The unloading station 203 serving as an unloading unit is configured to unload the multiple wafers W from the wafer processing system 200 to the outside or unload the wafers W from the main transfer chamber 210 to be described later.

The loading station 201 and the unloading station 203 have the same configuration as that of the loading/unloading station 2 in the above-described illustrative embodiment. Accordingly, an explanation thereof will be omitted.

In the processing station 202, there is provided the main transfer chamber 210 as a substrate transfer unit capable of depressurizing an inside thereof. The main transfer chamber 210 has, for example, a substantially rectangle shape when viewed from the top. Between the main transfer chamber 210 and the loading station 201, the first load-lock chamber 21 is provided, and between the main transfer chamber 210 and the unloading station 203, the second load-lock chamber 22 is provided. Further, the pre-processing device 23, the film forming device 26, the exposure device 27, and the developing device 28 are arranged in this sequence from the loading station 201 at a positive X-direction side (at an upward direction side of FIG. 6) of the main transfer chamber 210. The heat treatment devices 24, 25, and 25 and the dimension measuring device 29 are arranged in this sequence from the loading station 201 at a negative X-direction side (at a downward direction side of FIG. 6) of the main transfer chamber 210. Between the transfer chamber 11 and the respective load-lock chambers 21 and 22, between the main transfer chamber 210 and the respective load-lock chambers 21 and 22, and between the main transfer chamber 210 and the respective processing devices 23 to 29, there are provided gate valves 30 each configured to airtightly seal the space therebetween and also configured to be opened and closed. The load-lock chambers 21 and 22 and the processing devices 23 to 29 have the same configurations as those of the above-described illustrative embodiment. Accordingly, explanations thereof will be omitted.

The main transfer chamber 210 includes a transfer chamber 211 configured to seal the inside thereof. Within the transfer chamber 211, there is provided a wafer transfer device 212 configured to transfer the wafer W. The wafer transfer device 212 includes, for example, a transfer arm configured to be extensible and contractible in a horizontal direction and movable in a vertical direction, and rotatable about a vertical center (in a O-direction). Further, the wafer transfer device 212 can be moved within the transfer chamber 211, and can transfer the wafer W with respect to the load-lock chambers 21 and 22, and with respect to the processing devices 23 to 29 around the main transfer chamber 20.

In the wafer processing system 200 configured as described above, the wafer W is taken out of the cassette C on the cassette mounting table 10 in the loading station 201 by the wafer transfer body 13 and transferred to the first load-lock chamber 21. Then, the wafer W within the first load-lock chamber 21 is transferred into the main transfer chamber 210 by the wafer transfer device 212.

In the respective processing devices 23 to 29, preset processes are performed on the wafer W transferred into the main transfer chamber 210, and a resist pattern P is formed on the wafer W. The preset processes in the respective processing devices 23 to 29 are the same as those of the above-described illustrative embodiment. Accordingly, explanations thereof will be omitted.

Then, the wafer W within the main transfer chamber 210 is transferred to the second load-lock chamber 22 by the wafer transfer device 212. Thereafter, the wafer W is transferred to the cassette C on the cassette mounting table 10 in the unloading station 203 by the wafer transfer body 13. Thus, a series of wafer processes in the wafer processing system 1 is ended.

In the wafer processing system 200 of the present illustrative embodiment, a resist film R can be formed appropriately on the wafer W, and the resist pattern P can be formed appropriately. Therefore, the same effect as the above-described illustrative embodiment can be obtained.

In the wafer processing systems 1 and 200 of the above-described illustrative embodiments, arrangement or the number of the processing devices may be set selectively. By way of example, in the processing stations 3 and 202, the number of the processing devices may be changed depending on a processing time required for each process. Further, in the processing stations 3 and 202, there may be provided other processing devices such as a high-precision temperature control device configured to control a temperature of the wafer W with high accuracy.

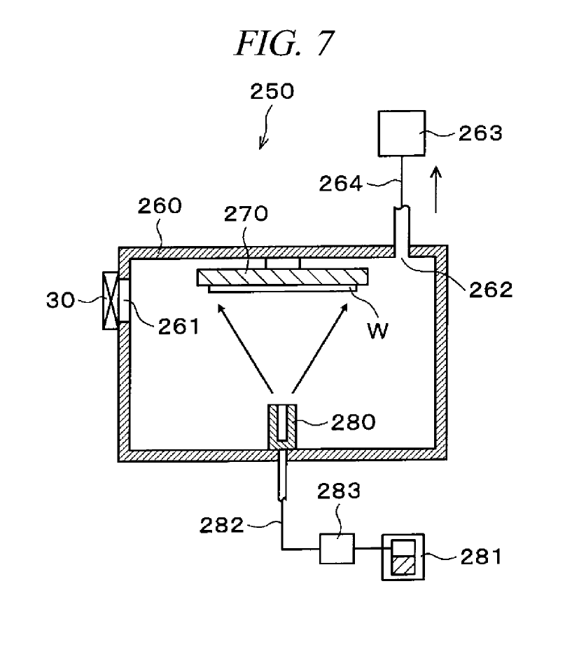

Further, a configuration of the film forming device is not limited to the configuration of the above-described illustrative embodiment, and any configuration may be employed if a low molecular resist can be deposited under a vacuum atmosphere. By way of example, as depicted in FIG. 7, a film forming device 250 includes a processing chamber 260 configured to accommodate wafers W and seals an inside thereof. At a side of the main transfer chamber 20 of the processing chamber 260, there is formed a loading/unloading port 261 through which the wafer W is loaded and unloaded. The above-described gate valve 30 is provided at the loading/unloading port 261.

At a ceiling surface of the processing chamber 260, there is formed an air intake opening 262 through which an atmosphere within the processing chamber 260 is depressurized to a certain vacuum atmosphere. By way of example, the air intake opening 262 is connected to an air intake line 264 configured to communicate with a vacuum pump 263.

At a ceiling surface within the processing chamber 260, there is provided a holding table 270 configured to horizontally hold the wafer W. The holding table 270 holds the wafer W by means of, for example, electrostatic attraction. Further, the wafer W is held on the holding table 270 in a face-down state where a surface on which a target film F is formed faces downwards.

Under the holding table 270, there is provided a so-called point source-typed deposition head 280. The deposition head 280 is connected to a vapor supply source 281 configured to supply a vapor of a low molecular resist to the deposition head 280 via a vapor supply line 282. The vapor supply line 282 includes a supply unit group 283 having a valve and a supply amount control unit that control a flow of the vapor of the low molecular resist.

In the film forming device 250, when the wafer W is held on the holding table 270, an inside of the processing chamber 260 is maintained under a certain vacuum atmosphere by the vacuum pump 263. Then, the vapor of the low molecular resist is supplied to the wafer W from the deposition head 280, and the low molecular resist is deposited on the wafer W, so that a resist film R is formed.

Further, in the film forming device 250, since the wafer W is held on the holding table 270 in the face-down state, an inverting device configured to invert front and rear surfaces of the wafer W is provided in the wafer processing systems 1 and 200.

In the present illustrative embodiment, the resist film R is formed on the wafer W in the film forming device 250. However, if a sacrificial film H and an anti-reflection film B are formed on the wafer W in the same manner as the above-described illustrative embodiment, a film forming device having the same configuration as that of the film forming device 250 is provided additionally. That is, a film forming device for forming a sacrificial film H and another film forming device for forming an anti-reflection film B are provided additionally.

As described above, in the wafer processing systems 1 and 200, the resist pattern P is formed on the wafer W. Then, outside the wafer processing system 1, the target film F on the wafer W is etched by using the resist pattern P as a mask. In this way, a semiconductor device is manufactured.

The above description of the illustrative embodiments is provided for the purpose of illustration but does not limit the present disclosure. It would be clearly understood by those skilled in the art that various changes and modifications may be made in the scope of the claims and it shall be understood that all modifications and embodiments conceived from the meaning and scope of the claims and their equivalents are included in the scope of the present disclosure. The present disclosure is not limited to the above-described illustrative embodiments and may be applied to various aspects. The present disclosure may be applied to other various substrates such as flat panel displays (FPDs) and mask reticles for photo mask in addition to the wafers.

### EXPLANATION OF CODES

1: Wafer processing system
2: Loading/unloading station
3: Processing station
20: Main transfer chamber
21: First load-lock chamber
22: Second load-lock chamber
23: Pre-processing device
24, 25: Heat treatment devices
26: Film forming device
27: Exposure device
28: Developing device
29: Dimension measuring device
50: Processing chamber
52: Air intake opening
53: Vacuum pump
54: Air intake line
60: Holding table
61: Driving unit
62: Rail
70: Sacrificial film deposition head
71: Anti-reflection film deposition head
72: Resist film deposition head
82: Supply opening
90: First electron beam irradiating unit
91: Second electron beam irradiating unit
100: Control device
110: Film thickness measuring device
200: Wafer processing system
201: Loading station
202: Processing station
203: Unloading station
210: Main transfer chamber
B: Anti-reflection film
F: Target film
H: Sacrificial film
R: Resist film
P: Resist pattern
W: Wafer

1. A film forming device of forming a resist film having a molecular resist of a low molecular compound on a substrate, the film forming device comprising:
a processing chamber configured to accommodate therein the substrate;
a holding table that is provided in the processing chamber and configured to hold the substrate thereon;
a resist film deposition head configured to supply a vapor of the molecular resist to the substrate held on the holding table; and
a depressurizing device configured to depressurize an inside of the processing chamber to a vacuum atmosphere.

2. The film forming device of claim 1, further comprising:
a sacrificial film deposition head configured to supply, onto a target film on the substrate, a vapor of a film forming material used in forming a sacrificial film that is formed between the target film and the resist film and serves as a mask when etching the target film;
an anti-reflection film deposition head configured to supply, onto the sacrificial film, a vapor of a film forming material used in forming an anti-reflection film formed between the sacrificial film and the resist film; and
a transfer device configured to transfer the substrate held on the holding table,
wherein the sacrificial film deposition head, the anti-reflection film deposition head, and the resist film deposition head are arranged in this sequence in a transfer direction of the substrate.

3. The film forming device of claim 2,
wherein each of the sacrificial film deposition head, the anti-reflection film deposition head and the resist film deposition head is configured to supply the vapor onto the substrate by using a carrier gas.

4. The film forming device of claim 2,
wherein each of the sacrificial film deposition head, the anti-reflection film deposition head and the resist film deposition head includes a supply opening, having a length greater than a length of the substrate, extended in a direction perpendicular to the transfer direction of the substrate, and the vapor is supplied onto the substrate through the supply opening.

5. The film forming device of claim 2, further comprising:
a first cross-linking unit provided between the sacrificial film deposition head and the anti-reflection film deposition head and configured to cross-link the sacrificial film; and
a second cross-linking unit provided between the anti-reflection film deposition head and the resist film deposition head and configured to cross-link the anti-reflection film.

6. A substrate processing system of forming a resist pattern having a molecular resist of a low molecular compound on a substrate, the substrate processing system comprising:
a film forming device configured to form a resist film on the substrate;
an exposure device configured to expose the formed resist film; and
a developing device configured to develop the exposed resist film,
wherein the film forming device comprises:
a processing chamber configured to accommodate therein the substrate;
a holding table that is provided in the processing chamber and configured to hold the substrate thereon;
a resist film deposition head configured to supply a vapor of the molecular resist to the substrate held on the holding table; and
a depressurizing device configured to depressurize an inside of the processing chamber to a vacuum atmosphere.

7. The substrate processing system of claim 6,
wherein the film forming device further comprises:
a sacrificial film deposition head configured to supply, onto a target film on the substrate, a vapor of a film forming material used in forming a sacrificial film that is formed between the target film and the resist film and serves as a mask when etching the target film;
an anti-reflection film deposition head configured to supply, onto the sacrificial film, a vapor of a film forming material used in forming an anti-reflection film formed between the sacrificial film and the resist film; and
a transfer device configured to transfer the substrate held on the holding table,
wherein the sacrificial film deposition head, the anti-reflection film deposition head, and the resist film deposition head are arranged in this sequence in a transfer direction of the substrate.

8. The substrate processing system of claim 7,
wherein each of the sacrificial film deposition head, the anti-reflection film deposition head and the resist film deposition head is configured to supply the vapor onto the substrate by using a carrier gas.

9. The substrate processing system of claim 7,
wherein each of the sacrificial film deposition head, the anti-reflection film deposition head and the resist film deposition head includes a supply opening, having a length greater than a length of the substrate, extended in a direction perpendicular to the transfer direction of the substrate, and the vapor is supplied onto the substrate through the supply opening.

10. The substrate processing system of claim 7,
wherein the film forming device further comprises:
a first cross-linking unit provided between the sacrificial film deposition head and the anti-reflection film deposition head and configured to cross-link the sacrificial film; and
a second cross-linking unit provided between the anti-reflection film deposition head and the resist film deposition head and configured to cross-link the anti-reflection film.

11. The substrate processing system of claim 6, further comprising:
a heat treatment device configured to perform a heat treatment on the substrate;
a dimension measuring device configured to measure a dimension of the resist pattern on the substrate after performing a developing process in the developing device; and
a control device configured to change at least one of a processing condition of the film forming device, a processing condition of the exposure device and a processing condition of the heat treatment device based on a measurement result of the dimension measuring device.

12. The substrate processing system of claim 6, further comprising:
a film thickness measuring device configured to measure a film thickness of the resist film on the substrate after performing a film forming process in the film forming device; and
a control device configured to change a processing condition of the film forming device based on a measurement result of the film thickness measuring device.

13. The substrate processing system of claim 11,
wherein the processing condition of the film forming device includes at least one of a temperature and a supply amount of the vapor of the molecular resist.

14. The substrate processing system of claim 11,
wherein the processing condition of the film forming device includes a supply flow rate of a carrier gas configured to transfer the vapor of the molecular resist.

15. The substrate processing system of claim 6, further comprising:
a substrate transfer unit configured to transfer the substrate to the film forming device, the exposure device, and the developing device; and
a substrate loading/unloading unit configured to load and unload the substrate with respect to the substrate transfer unit.

16. The substrate processing system of claim 6, further comprising:
a substrate transfer unit configured to transfer the substrate to the film forming device, the exposure device, and the developing device;
a substrate loading unit configured to load the substrate into the substrate transfer unit; and
a substrate unloading unit configured to unload the substrate from the substrate transfer unit.

17. The substrate processing system of claim 6, further comprising:
a pre-processing device configured to clean a surface of the substrate before performing a film forming process in the film forming device.

18-26. (canceled)

27. A semiconductor device manufacturing method comprising:
forming a resist pattern having a molecular resist of a low molecular compound on a substrate by performing a substrate processing method; and
etching a target film on the substrate by using the resist pattern as a mask after forming the resist pattern,
wherein the substrate processing method comprises:
forming a resist film by supplying a vapor of the molecular resist onto the substrate and depositing the molecular resist on the substrate under a vacuum atmosphere;
performing a first heat treatment on the resist film after forming the resist film;
exposing the resist film after performing the first heat treatment;
performing a second heat treatment on the resist film after exposing the resist film;
developing the resist film after performing the second heat treatment; and
performing a third heat treatment on the resist film after developing the resist film.
